(19) United States
(12) Patent Application Publication
(10) Pub. No.: US 2013/0193603 A1
(43) Pub. Date: Aug. 1, 2013

(54) INSPECTION APPARATUS, LITHOGRAPHY APPARATUS, IMPRINT APPARATUS, AND METHOD OF MANUFACTURING ARTICLE

(71) Applicant: CANON KABUSHIKI KAISHA, Tokyo (JP)

(72) Inventor: Akihiro Yamada, Utsunomiya-shi (JP)

(73) Assignee: CANON KABUSHIKI KAISHA, Tokyo (JP)

(21) Appl. No.: 13/752,598

(22) Filed: Jan. 29, 2013

(30) Foreign Application Priority Data
Feb. 1, 2012 (JP) 2012-020306
Dec. 21, 2012 (JP) 2012-280066

(51) Int. Cl. G01B 11/30

(52) U.S. Cl. CPC G01B 11/303; H01L 22/12
USPC 264/40.3; 356/600; 356/72; 425/169

(57) ABSTRACT

A foreign substance inspection apparatus includes: an irradiation unit configured to irradiate a surface of an object to be inspected with inspection light; a detector configured to detect light scattered by the surface irradiated with the inspection light; a determination unit configured to determine, using data of a surface roughness of the object, and data of a size of the foreign substance, an irradiated region of the inspection light on the surface, that allows light scattered by the foreign substance to be discriminated from light scattered by the object due to the surface roughness of the object; and a controller configured to control the irradiation unit so as to irradiate the irradiated region determined by the determination unit with the inspection light.

### BACKGROUND OF THE INVENTION

1. Field of the Invention

The present invention relates to an inspection apparatus, a lithography apparatus, an imprint apparatus, and a method of manufacturing an article.

2. Description of the Related Art

An exposure apparatus is generally employed in a photolithography process for manufacturing a semiconductor integrated circuit. In recent years, an imprint technique in which an original (mold) having a fine pattern formed on it by, for example, electron beam exposure is pressed (impressed) against a substrate such as a wafer coated with a resin material, and the resin is cured to transfer the pattern onto the substrate is expected to be applied to the photolithography process as well.

In the lithography process, when a foreign substance is present on the wafer, this causes a defect in the device pattern, thus lowering the yield of the device manufacture. In the imprint technique, when a foreign substance is present on the wafer, this causes a defect or fracture in the original at, the time of imprinting. For this reason, an inspection apparatus capable of detecting a foreign substance on the wafer is necessary in the device manufacturing process.

As such a foreign substance inspection apparatus, a dark field inspection apparatus which focuses a laser beats on a wafer to be inspected, irradiates the wafer with the laser beam, and receives light scattered by a foreign substance, thereby inspecting the wafer for the foreign substance in accordance with a signal of the scattered right is known well. The dark field inspection apparatus must discriminate between light scattered by the foreign substance on the wafer surface, and light scattered by the wafer due to its surface roughness.

With miniaturization of semiconductor devices, the size of a foreign substance required to be detected is becoming very small. As the size of a foreign substance to foe detected reduces, the intensity of light scattered by the foreign substance decreases, thus making it difficult to discriminate between this light and light scattered by the wafer due to its surface roughness. Hence, the laser beam to be guided onto the wafer is focused at a size on the order of several to several ten micrometers or less to reduce the influence of light scattered by the foreign substance on light scattered by the wafer due to its surface roughness (Japanese Patent Laid-Open No. 06-194320).

As the focus size of inspection light reduces, the inspect ion throughput lowers, thus making it necessary to raise the stage speed. The recent general, dark field inspection apparatus performs detection while rotating the stage at a speed on the order of several, thousand rpm. The technique of dark field inspection for a foreign substance is used not only for inspection on a wafer hut also for inspection on a reticle and pellicle. The tolerance of the size of a foreign substance is different between a reticle and a pellicle. Hence, the focus size is determined based on the information of the tolerances of the sizes of foreign substances for a pellicle and reticle, respectively, thereby efficiently inspecting them for foreign substances (Japanese Patent No. 2671896).

In recent years, a demand has arisen for inspection of a foreign substance immediately before exposure in terms of further improving the yield of the semiconductor manufacturing process, so in-line measurement in the exposure apparatus is required. Since a high-speed stage becomes a vibration source and leads to degradation in exposure accuracy including overlay accuracy, it is difficult to raise the stage speed in in-line measurement. Even if this can be achieved, the exposure apparatus may increase in size and cost due to the necessity of a high-power light source and precise control. If a foreign substance is to be detected in a short time by a compact arrangement that can be placed in the exposure apparatus, it may be impossible to measure the required size of a foreign substance.

The surface roughness to be inspected varies in each individual device manufacturing process in foreign substance inspection on a water, unlike foreign substance inspection on a reticle and pellicle. As the size of a foreign substance reduces, the intensity of light scattered by the foreign substance decreases, thus making it difficult to discriminate between this light and light scattered by the wafer due to its surface roughness.

### SUMMARY OF THE INVENTION

The present invention provides a detector which efficiently detects a foreign substance to be detected.

The present invention provides an inspection apparatus of performing inspection of a surface of an object to be inspected for a foreign substance, the apparatus comprising: an irradiation unit configured to irradiate the surface with inspection light; a detector configured to detect light scattered by the surface irradiated with the inspection light; a determination unit configured to determine, using data, of a surface roughness of the object, and data of a size of the foreign substance to be detected by inspection, an irradiated region of the inspection light on the surface, that allows light scattered by the foreign substance to be discriminated iron light scattered by the object due to the surface roughness of the object; and a controller configured to control the irradiation unit so as to irradiate the irradiated region determined by the determination unit with the inspection light.

Further features of the present invention will become apparent from the following description of exemplary embodiments with reference to the attached drawings.

### BRIEF DESCRIPTION OF THE DRAWINGS

FIG. 1 is a view for explaining dark field inspection;

FIG. 2 is a graph showing the PSD of the surface roughness;

FIGS. 3A and 3B are graphs each showing the optical S/N ratio at the time of foreign substance inspection;

FIG. 4 is a view showing a foreign substance inspection apparatus; and

FIG. 5 is a flowchart of foreign substance inspection.

### DESCRIPTION OF THE EMBODIMENTS

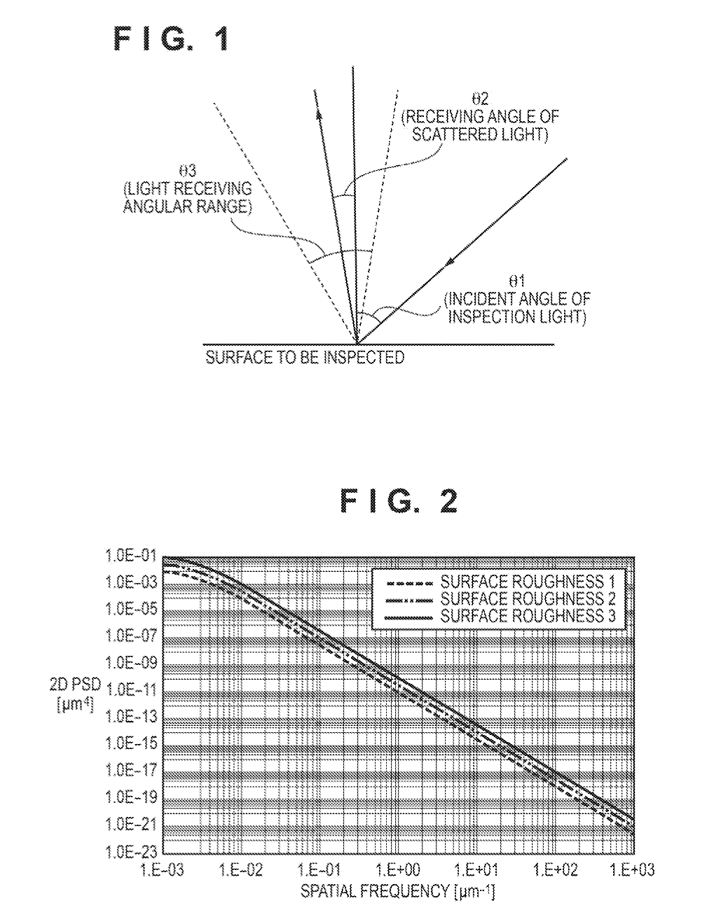

Embodiments of the present invention will be described in detail below with reference to the accompanying drawings. FIG. 1 is a view for explaining dark field inspection for a foreign substance. In the dark field inspection, inspection light is focused to have a given shape and size at an angle 81, the surface of an object to be inspected is irradiated with the inspection light, light which is scattered by a foreign substance adhered on the object or by the surface of the object is received within a light receiving angular range θ3 having a light receiving angle θ2 as its center by a light receiving optical system, and the received light is guided to a detector, thereby detecting the foreign substance.

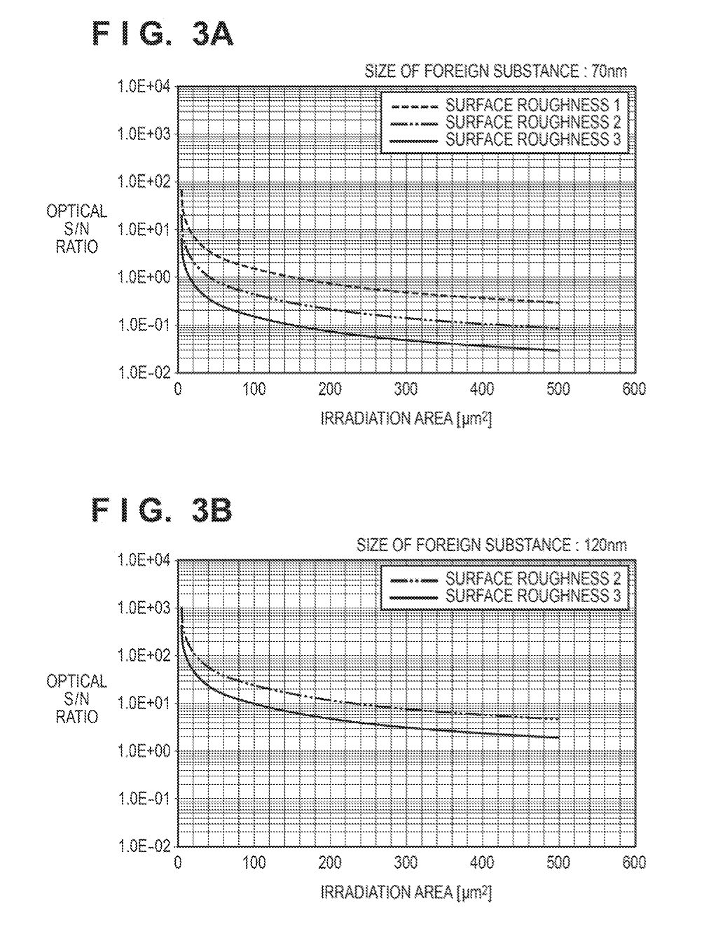

FIGS. 3A and 3B illustrate examples of the simulation results of the relationship between the size of the irradiated region and the optical S/N ratio. The optical S/N ratio means the ratio between the intensity S of light which is scattered by a foreign substance and received by the light receiving optical system, and the intensity N of light scattered by the object due to its surface roughness. Inspection light was non-polarized light emitted by a 488-nm argon ion laser, the illumination angle θ1 was 60% the light receiving angle θ2 was 0% and the scattered light receiving angular range θ3 was 10°. A wafer to be inspected (object) was coated, with a thin film having a refractive index of 1.65, an attenuation coefficient of 0.35, and a thickness of 100 nm. The surface roughness of the wafer was assumed to be represented by three patterns of the PSD (Power Spectral Density) of the surface shape, as shown in FIG. 2. Surface roughness 3 is higher than surface roughness 2, which is higher than surface roughness 1. The two-dimensional PSD of the surface roughness, and the angular distribution of scattered, light satisfy:

$$\frac{d {L}_{0}}{{L}_{i} cos {θ}_{i} d {ω}_{i}} = \frac{16 {π}^{2}}{{λ}^{4}} cos {θ}_{i} cos {θ}_{s} {QS}_{2} ( f ) \qquad ( 1 )$$

where λ is the light wavelength, θ₁ is the incident angle, θₛ is the scattering angle, ωi is the incident direction of the light beam, Q is the polarization factor, S₂ (f) is the PSD, L₀ is the emerging spectral radiance, and Lᵢ is the incident spectral radiance. The polarisation factor Q can be calculated as the characteristics of incident polarised light, the incident angle, and the refractive index of the substrate are determined. Therefore, to calculate the angular distribution of light scattered by the wafer due to its surface roughness, it is only necessary to determine the incident spectral radiance L₁ and the two-dimensional PSD in advance.

FIG. 3A shows the relationship between the size of the irradiated region and the optical s/N ratio when each surface roughness shown in FIG. 2 is assumed for a foreign substance with a size of 70 nm. The minimum optical S/N ratio at which light scattered by the foreign substance can be discriminated from light scattered by the wafer due to its surface roughness varies in each individual detector and signal processing circuit which constitute the apparatus, but signals of these two scattered light beams can generally be discriminated when the optical S/N ratio satisfies a condition;

Optical S/N Ratio>5 (2)

When the optical S/N ratio becomes 5 or less, it becomes difficult to discriminate between noise signals in the detector and signal processing system, and a signal, of light scattered by the foreign substance.

As can be seen from FIG. 3A, the irradiated region which satisfies inequality (2) varies depending on the surface roughness. To satisfy inequality (2), the area of the irradiated region must, be set to 28 μm² or less for surface roughness 1. Similarly, to satisfy inequality (2), the area of the irradiated region must be set to 7 μm² or less for surface roughness 2, and 2 μm² or less for surface roughness 3. FIG. 3B shows the relationship between the size of the irradiated region and the optical S/N ratio when each surface roughness shown in FIG. 2 is assumed for a foreign substance with a size of 120 nm. To satisfy inequality (2), the area of the irradiated region must be set to 468 μm² or less for surface roughness 2. Similarly, to satisfy inequality (2), the area of the irradiated region must be set to 188 μm² or less for surface roughness 3.

As can be seen from the foregoing description, the size required for the irradiated region varies depending not only on the difference in size of a foreign substance but also on the difference in surface roughness of the wafer as the object. Since a semiconductor device has a multilayered circuit pattern structure, a lithography apparatus forms a circuit pattern for each layer. Also, since the pitch and configuration of the circuit pattern vary in each individual layer, the manufacturing process and the tolerance of a defect due to the presence of a foreign substance also vary in each individual layer. When the manufacturing process varies, the surface roughness of the wafer also varies. On the other hand, a reticle and pellicle have little difference in surface roughness for each lot. Therefore, in foreign substance inspection on a wafer, neither the shape nor size of an irradiated region can be determined only from the size of a foreign substance, as described in Japanese Patent No. 2671896. In foreign substance inspection on a wafer, the shape and size of an irradiated region must be determined from both data of the size of a foreign substance to be detected by inspection, and data of the surface roughness of the object.

On the other hand, the amount of scattered light, which is required for a detector, is determined from the sensitivity of the detector. The amount of light detected by the detector is determined by the irradiation intensity of inspection light, and the time taken for the irradiated region to pass through the foreign substance. The time taken for the irradiated region to pass through the foreign substance is determined from the size of the irradiated region, and the moving speed of the stage relative to the inspection light. Therefore, as the irradiation intensity and the size of the irradiated region are determined, the tolerance of the relative moving speed of the stage in obtaining the required amount of scattered light is determined. An embodiment of the present invention will be described below.

### Embodiment

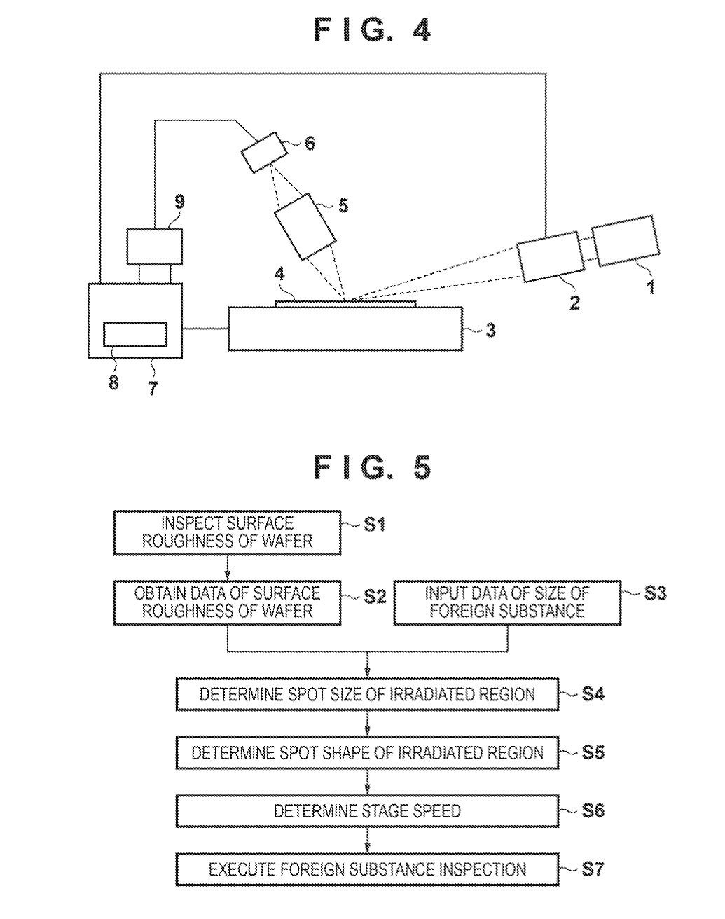

FIG. 4 is a conceptual view illustrating an example of a foreign substance inspection apparatus according to an embodiment of the present invention. The foreign substance inspection, apparatus is configured in a lithography apparatus (not shown) as a unit. Lithography apparatuses to which the foreign substance inspection apparatus according to this embodiment is applicable include an imprint apparatus which brings a mold into contact with a resin applied on a substrate, and cures the resin, thereby forming a pattern on the resin, an exposure apparatus which exposes a substrate to light, and a drawing apparatus which draws on a substrate with a charged particle beam.

Referring to FIG. 4, a light source 1 emits inspection light. As the light source 1, a laser diode, an argon ion laser, or a YAG laser can be used. An illumination optical system 2 includes an adjusting mechanism which irradiates the surface of a wafer (substrate) 4 as an object to be inspected with the inspection light, which is emitted by the light source 1 and has a desired spot shape and size. The adjusting mechanism means herein a mechanism which switches between, for example, a plurality of apertures having different sizes. The adjusting mechanism serves as, for example, an optical element zoom mechanism provided in the illumination optical system 2, and may serve as a mechanism which continuously changes the spot size. The light source 1, illumination optical system 2, and adjusting mechanism constitute an irradiation unit which irradiates the surface of the wafer 4 with inspection light having a controlled irradiated region.

A stage 3 holds the wafer 4 to be inspected, and rotates and rectilinearly moves it. In this embodiment, the illumination optical system 2 is fixed, and the stage 3 is movably set. However, the illumination optical system 2 may be movably set, so that the stage 3 moves relative to the illumination optical system 2. By rotating and rectilinearly moving the stage 3, the entire surface of the wafer 4 can be inspected for a foreign substance. The rotation speed of the stage 3 can be adjusted. The wafer 4 to be inspected has a surface roughness which varies depending on the difference in manufacturing step-specific process. A light receiving optical system 5 focuses light scattered by the irradiated region on the surface of the wafer 4. The light receiving optical system 5 focuses, on a detector 6, not only light scattered by a foreign substance but also light scattered by the wafer surface.

The detector 6 is implemented by, for example, a photomultiplier or a photodiode. The detector 6 amplifies the scattered light focused by the light receiving optical system 5, and photoelectrically converts it. A voltage signal obtained by the detector 6 is converted into a numerical value by A/D-converting voltage signals sampled at a predetermined time interval in a signal processing circuit system (not-shown). The obtained numerical value corresponds to the intensity of scattered light. A controller 7 controls the overall lithography apparatus, and includes a system which controls the spot sire of the irradiated region of inspection light, a system which controls the relative moving speed of the stage 3, and an external input unit (obtaining unit) 8. Data of the size of a foreign substance to be detected by inspection, and PSD data of the surface roughness can be externally input using the external input unit 8. A determination unit 9 calculates the difference in sire of foreign substances from the signal processing result, calculates the intensity of scattered light from the foreign substance size information, and calculates the intensity and optical S/N ratio of the scattered light from the roughness information of the surface of the object.

FIG. 5 shows the sequence of foreign substance inspection. In step S1, the foreign substance inspection apparatus irradiates the wafer 4 to be inspected, which is set on the stage 3, with inspection light to inspect the surface roughness. At this time, the irradiated region of the inspection light desirably has a spot size as large as, for example, 500 μm² or more and, more specifically, 1 mm² or more within the range in which the light receiving optical system 5 can receive the inspection light. As the spot size of the irradiated region increases, the intensity of light scattered by a foreign substance becomes lower than that of light scattered by the wafer 4 due to its surface roughness. Hence, the intensity of light scattered by the foreign substance can foe ignored, so the obtained signal of the scattered light can be regarded to represent the intensity of light-scattered by the wafer 4 due to its surface roughness. Also, there is no need to scan the entire surface of the wafer 4, so signal intensities may be measured only at several representative points to estimate data of the surface roughness from their average signal intensity. Because signal intensities are measured only at several points, the inspection time does not increase considerably. In this manner, the foreign substance inspection apparatus obtains data of the surface roughness of the wafer 4 upon surface roughness inspection in advance (step S2).

In step S3, data of the size of a foreign substance to be detected by inspection, which is required in each device manufacturing step, is input from the external input unit 8. In step S1, the determination unit 9 calculates the intensity of light scattered by the foreign substance and that of light scattered by the wafer 4 due to its surface roughness when the spot size of the irradiated region is used as at parameter, based on the surface roughness of the wafer 4 obtained in step S2, and the size of the foreign substance input in step S3, thereby obtaining the optical S/N ratio. The determination unit 9 then determines the spot size of the irradiated region, at which the obtained optical S/N ratio has a value that satisfies a tolerance set in advance. At this time, instead of calculating the intensity of light scattered by the foreign substance in each operation, the determination unit 9 may obtain the intensity of light-scattered by the foreign substance based on a table representing the relationship between the intensity of scattered light and the spot size of the irradiated region for each size of a foreign substance. Similarly, the intensity of light scattered by the wafer surface may also be held in the form of a table.

In step S5, the determination unit 9 determines the spot shape of the irradiated region. In step S6, the determination unit 9 determines the relative moving speed of the stage 3, including the rotation speed and rectilinear moving speed at the time of foreign substance inspection, so as to obtain the amount of light required for the detector 6. If the spot shape of the irradiated region is determined so that the spot dimension in a direction perpendicular to that in which the stage 3 rotates is smaller than that in the direction in which the stage 3 rotates, the time taken for the irradiated region to pass through the foreign substance prolongs in measuring the foreign substance, so the total amount of light scattered by the foreign substance increases. On the other hand, because the spot region on the wafer 4 in the radial direction is short, it is necessary to lower the rectilinear moving speed of the stage 3 when the entire surface of the wafer 4 is measured.

If the spot shape of the irradiated region is determined so that the spot dimension in a direction perpendicular to that in which the stage 3 rotates is larger than that in the direction in which the stage 3 rotates, the time taken for the irradiated region to pass through the foreign substance shortens in measuring the foreign substance, so the total amount of light scattered by the foreign substance decreases. On the other hand, because the spot region on the wafer 4 in the radial direction is long, it is possible to raise the rectilinear moving speed of the stage 3. Based on the required amount of light determined from the sensitivity of the detector 6, the determination unit 9 determines the spot shape of the irradiated region so as to maximize the allowable stage speed.

The controller 7 adjusts the illumination optical system 2 in accordance with the size and shape of the irradiated region, which are determined in steps S4 and S5, respectively. Similarly, the controller 7 sets the rotation speed of the stage 3 in accordance with the speed determined in step S6. In step S7, the foreign substance inspection apparatus performs foreign substance inspection while moving the stage 3 relative to the illumination optical system 2 at the determined relative moving speed. In this manner, the shape and size of the irradiated region, and the relative moving speed of the stage 3 are determined based on data of the surface roughness and the size of a foreign substance to be detected by inspection, thereby reliably inspecting the foreign substance in a short time.

The roughness of the wafer surface may be measured in advance instead of inspecting the surface roughness in step S1 to obtain information of the surface roughness of the wafer 4. The distribution of light scattered by the wafer 4 due to its surface roughness can be estimated by measuring the surface roughness at several points on the wafer 4 using, for example, an AFM (Atomic Force Microscope), and obtaining the PSD from the measurement result.

Hence, the obtained data of the surface roughness may be input via the external input unit 8, and the intensity distribution of light scattered by the wafer 4 due to its surface roughness may be calculated inside. Alternatively, the wafer surface roughness in the same manufacturing process may foe set to be the same, and held in the determination unit 9 in the form of a table as the intensity data or PSD information data of light scattered by the wafer 4 due to its surface roughness for each process in advance.

[Imprint Method]

The case wherein an inspection apparatus according to the present invention is configured in an imprint apparatus as a unit will be described. The imprint apparatus brings a mold having a pattern formed on it into contact with a resin (imprint material) supplied onto a substrate to form a pattern on the substrate. If a foreign substance is present on the substrate, it may damage the mold upon bringing the mold into contact with the resin. Therefore, when the imprint apparatus is used, it is necessary to inspect the presence/absence of a foreign substance before a pattern is formed. To meet this requirement, before a pattern is formed on a substrate by the imprint apparatus, the substrate is inspected for a foreign substance by the above-mentioned inspection apparatus, and loaded into the imprint apparatus.

More specifically, a substrate on which a pattern is to be transferred next by the imprint apparatus is loaded into the inspection apparatus, and inspected for a foreign substance. At this time, data of the size of a foreign substance to be detected by inspection can be obtained from the size of a pattern to be formed by the imprint apparatus. The data of the size of a foreign substance represents the minimum value of the size of a foreign substance that can be detected by the inspection apparatus. That is, this data represents the resolution of the inspection apparatus. A foreign substance having a size larger than that set in the data of the size of a foreign substance can be detected. Either the entire surface of a substrate or a partial region on the substrate may be inspected for a foreign substance.

When a partial region on the substrate is inspected, a pattern is formed on the entire surface of the substrate by repeating a foreign substance inspection process, and a process of forming a pattern in the inspected region by the imprint apparatus. As a partial region on the substrate, a region (shot region) with a size equal to that of the pattern formed on the mold can be set. After a shot region is inspected for a foreign substance, a dispensing device (dispenser) arranged in the imprint apparatus is used to supply a resin to the inspected, shot region. The mold having the pattern formed on it is aligned with the shot region dispensed with the resin, and is brought into Contact with the resin. The resin is cured while the mold is kept in contact with the resin to form a pattern on the substrate. After pattern formation, a shot region in which a pattern is to be formed next is inspected for a foreign substance. In this mariner, by repeating foreign substance inspection and pattern formation for each shot region, foreign substance inspection can be performed immediately before a pattern is formed on the substrate.

If a foreign substance is detected on the substrate by the foreign substance inspection apparatus, no pattern is formed in a shot region having the foreign substance upon determining this shot region as an error snot, or a process of removing the foreign substance is performed. However, when each shot region includes a plurality of chips, if a foreign substance in a certain shot region is small enough not to damage the mold, an imprint process is performed to form a pattern on the substrate. The information of a chip region having a foreign substance detected by the inspection apparatus is stored as an error chip. By configuring an inspection apparatus according to the present invention in an imprint apparatus as a unit, foreign substance inspection can be performed while suppressing a decrease in throughput.

[Embodiment of Method of Manufacturing Article]

A method of manufacturing a device (for example, a semiconductor integrated circuit device or a liquid crystal display device) as an article includes a step of transferring (forming) a pattern onto a substrate (a wafer, a glass plate, or a film-like substrate) using the above-mentioned imprint apparatus. This method can also include a step of etching the substrate having the pattern transferred onto it. Note that when other articles such as a patterned medium (recording medium) and an optical element are to be manufactured, this method can include other processes of processing the substrate having the pattern transferred onto it, instead of etching.

While the present invention has been described with reference to exemplary embodiments, it is to be understood that the invention is not limited to the disclosed exemplary embodiments. For example, although the shape of the illuminated region is limited to a spot shape in this embodiment, a rectangular illumination shape may be used. Also, when a rectangular illumination shape is used, the stage which performs rotation and rectilinear driving may be replaced with an X-Y stage, and the photoelectric detector may be replaced with a CCD or a CMOS. The scope of the following claims is to be accorded the broadest interpretation so as to encompass all such modifications and equivalent structures and functions.

This application claims the benefit of Japanese Patent Application No. 2012-020306 filed Feb. 1, 2012, and No. 2012-280066 filed Dec. 21, 2012, which are hereby incorporated by reference herein in their entirety.

What is claimed is:

1. An inspection apparatus of performing inspection of a surface of an object to be inspected for a foreign substance, the apparatus comprising:
an irradiation unit configured to irradiate the surface with inspection light;
a detector configured to detect light scattered by the surface irradiated with the inspection light;
a determination unit configured to determine, using data of a surface roughness of the object, and data of a size of the foreign substance to be detected by inspection, an irradiated region of the inspection light on the surface, that allows light scattered by the foreign substance to be discriminated from light scattered by the object due to the surface roughness of the object; and
a controller configured to control said irradiation unit so as to irradiate the irradiated region determined by said determination unit with the inspection light.

2. The apparatus according to claim 1, further comprising
a stage capable of moving relative to said irradiation unit while holding the object in the inspection,
wherein said determination unit determines a relative moving speed of said stage so as to obtain scattered light in an amount required for said detector, based on the two data, and
said controller allows the apparatus to perform the inspection while moving said stage relative to said irradiation unit at the determined relative moving speed.

3. The apparatus according to claim 1, wherein the data of the surface roughness includes a power spectral density of a surface shape of the object.

4. The apparatus according to claim 1, further comprising an obtaining unit configured to obtain the data of the surface roughness of the object, and the data of the size of the foreign substance to be detected by inspection.

5. The apparatus according to claim 1, wherein said determination unit calculates, using data of a surface roughness of the object, and data of a size of the foreign substance to be detected by inspection, an intensity of light scattered by the foreign substance and an intensity of light scattered by the object due to the surface roughness of the object when an irradiated region of the inspection light on the surface changes, thereby determining the irradiated region of the inspection light on the surface based on a ratio between the intensity of the light scattered by the foreign substance and the intensity of the light scattered by the object due to the surface roughness of the object.

6. An inspection apparatus of performing inspection of a surface of an object to be inspected for a foreign substance, the apparatus comprising:
an irradiation unit configured to irradiate the surface with inspection light;
a detector configured to detect light scattered by the surface irradiated with the inspection light;
a determination unit configured to determine, using data of a surface roughness of the object, and data of a size of the foreign substance to be detected by inspection, an irradiated region of the inspection light on the surface; and
a controller configured to control said irradiation unit so as to irradiate the irradiated region determined by said determination unit with the inspection light.

7. A method of performing inspection of a surface of an object to be inspected for a foreign substance by irradiating the surface of the object with inspection light having a controlled irradiated region while moving the object relative to the inspection light, and detecting light scattered by the surface irradiated with the inspection light, the method comprising:
determining, based on data of a surface roughness of the object, and data of a size of the foreign substance to be detected by inspection, an irradiated region of the inspection light on the surface, that allows light scattered by the foreign substance to be discriminated from light scattered by the object due to the surface roughness of the object; and
performing the inspection while controlling the inspection light to have the determined irradiated region.

8. The method according to claim 7, further comprising
irradiating the object with inspection light having an irradiated region larger than the determined irradiated region, and detecting light scattered by the surface irradiated with the inspection light to measure the surface roughness of the object, thereby obtaining data of the surface roughness of the object.

9. A method of performing inspection of a surface of an object to be inspected for a foreign substance by irradiating the surface of the object with inspection light having a controlled irradiated region while moving the object relative to the inspection light, and detecting light scattered by the surface irradiated with the inspection light, the method comprising:
inspecting a surface roughness of the object;
determining, based on data of the surface roughness of the object, and data of a size of the foreign substance to be detected by inspection, an irradiated region of the inspection light on the surface, that allows light scattered by the foreign substance to be discriminated from light scattered by the object due to the surface roughness of the object; and
performing the inspection while controlling the inspection light to have the determined irradiated region.

10. A lithography apparatus of forming a pattern on a substrate, the apparatus comprising
an inspection apparatus configured to inspect a surface of the substrate for a foreign substance,
said inspection apparatus including:
an irradiation unit configured to irradiate the surface with inspection light;
a detector configured to detect light scattered by the surface irradiated with the inspection light;
a determination unit configured to determine, using data of a surface roughness of the object, and data of a size of the foreign substance to be detected by inspection, an irradiated region of the inspection light on the surface, that allows light scattered by the foreign substance to be discriminated from light scattered by the object due to the surface roughness of the object; and
a controller configured to control said irradiation unit so as to irradiate the irradiated region surface determined by said determination unit with the inspection light.

11. A method of manufacturing an article, the method comprising:
forming a pattern on a substrate using a lithography apparatus;
developing the substrate having the pattern formed thereon; and
processing the developed substrate to manufacture the article,
the lithography apparatus comprising
an inspection apparatus configured to inspect a surface of the substrate for a foreign substance,
the inspection apparatus including:
an irradiation unit configured to irradiate the surface with inspection light;
a detector configured to detect light scattered by the surface irradiated with the inspection light;
a determination unit configured to determine, using data of a surface roughness of the object, and data of a size of the foreign substance to be detected by inspection, an irradiated region of the inspection light on the surface, that allows light scattered by the foreign substance to be discriminated from light scattered by the object due to the surface roughness of the object; and
a controller configured to control the irradiation unit so as to irradiate the irradiated region determined by the determination unit with the inspection light.

12. An imprint apparatus of forming a pattern on an imprint material, supplied onto a surface of a substrate, using a mold having a pattern formed thereon, the apparatus comprising:
an inspection apparatus configured to inspect the surface of the substrate for a foreign substance,
said inspection apparatus including:
an irradiation unit configured to irradiate the surface with inspection light;
a detector configured to detect light scattered by the surface irradiated with the inspection light;
a determination unit configured to determine, using data of a surface roughness of the substrate, and data of a size of the foreign substance to be detected by inspection, an irradiated region of the inspection light on the surface; and
a controller configured to control said irradiation unit so as to irradiate the irradiated region determined by said determination unit with the inspection light.

13. The apparatus according to claim 12, wherein
said inspection apparatus inspects the entire surface of the substrate, and
the imprint material is supplied from a supply unit arranged in the imprint apparatus onto the surface of the substrate to form a pattern on the imprint material supplied onto the surface of the substrate.

14. The apparatus according to claim 12, wherein
said inspection apparatus inspects a partial region on the surface of the substrate, and
the imprint material is supplied from a supply unit arranged in the imprint apparatus onto the surface of the substrate in the region inspected by said inspection apparatus to form a pattern on the imprint material supplied onto the surface of the substrate.

15. The apparatus according to claim 14, wherein the pattern is formed on the substrate by repeating foreign substance inspection by said inspection apparatus and pattern formation by the imprint apparatus.
